(19) United States
(12) Patent Application Publication
(10) Pub. No.: US 2026/0298993 A1
(43) Pub. Date: Oct. 1, 2026

(54) TEST DEVICE

(71) Applicant: LEENO INDUSTRIAL INC., Busan (KR)

(72) Inventors: Jaehwan JEONG, Busan (KR); Jaehun KIM, Busan (KR)

(73) Assignee: LEENO INDUSTRIAL INC., Busan (KR)

(21) Appl. No.: 19/477,255

(22) PCT Filed: Apr. 1, 2024
(86) PCT No.: PCT/KR2024/004150

§ 371 Date: Oct. 21, 2025

(30) Foreign Application Priority Data
Apr. 25, 2023 (KR) 10-2023-0054194

(51) Int. Cl. G01R 29/10; G01R 1/04; G01R 1/24; G01R 31/28

(52) U.S. Cl. CPC G01R 29/10; G01R 1/0441; G01R 1/24; G01R 31/282

(57) ABSTRACT

Disclosed is a test device for testing characteristics of a subject-to-be-tested with a built-in antenna that emits a wireless signal. The test device includes: a signal probe including one end portion to be in contact with a first terminal of the subject-to-be-tested to transmit a test signal; a ground probe to be in contact with a second terminal of the subject-to-be-tested; and a socket block including a probe supporter to support the signal probe and the ground probe, and a waveguide corresponding to the antenna of the subject-to-be-tested and penetrating therethrough in a lengthwise direction of the signal probe to measure the wireless signal in a different area from the probe supporter.

### TECHNICAL FIELD

The disclosure relates to a test device for testing the characteristics of a subject-to-be-tested with a built-in antenna that emits a wireless signal.

### BACKGROUND ART

Recently, a subject-to-be-tested, i.e., a semiconductor device includes a built-in patch antenna. Accordingly, there is required a test device capable of evaluating the characteristics of the built-in antenna of the semiconductor device.

### DISCLOSURE

### Technical Problem

An aspect of the disclosure is to provide a test device for testing the characteristics of a subject-to-be-tested including a built-in antenna that emits a wireless signal.

### Technical Solution

According to an embodiment of the disclosure, there is provided a test device. The test device includes a signal probe including one end portion to be in contact with a first terminal of the subject-to-be-tested to transmit a test signal; a ground probe to be in contact with a second terminal of the subject-to-be-tested; and a socket block including a probe supporter to support the signal probe and the ground probe, and a waveguide corresponding to the antenna of the subject-to-be-tested and penetrating therethrough in a lengthwise direction of the signal probe to measure the wireless signal in a different area from the probe supporter.

The waveguide may include a shielding wall protruding from one side of the socket block facing the subject-to-be-tested toward the antenna.

The shielding wall may have a height set to satisfy loss characteristics of the wireless signal when the first terminal and the second terminal of the subject-to-be-tested are in contact with the signal probe and the ground probe, respectively.

The shielding wall may include terminal guide grooves recessed along a test direction to guide the second terminal to move down upon a test.

The probe supporter and the waveguide may include a conductive material.

The probe supporter may be made of an insulating material. The waveguide may be made of a conductive material. The socket block may include a conductive connector that connects the ground probe and the waveguide.

### Advantageous Effects

The test device according to an embodiment of the disclosure tests not only the electrical characteristics of the subject-to-be-tested but also the characteristics of the built-in patch antenna at a time, thereby reducing test time and test costs.

### DESCRIPTION OF DRAWINGS

FIG. 1 is a view showing a subject-to-be-tested viewed from below.

FIG. 2 is a perspective view of a test device according to an embodiment of the disclosure.

FIG. 3 is an exploded perspective view of the test device in FIG. 2.

FIG. 4 is a perspective view of a socket block in FIG. 2 viewed from above.

FIG. 5 is a perspective view of the socket block of FIG. 2 vied from below.

FIG. 6 is a cross-sectional view taken along line A-A in FIG. 4.

FIG. 7 is an enlarged cross-sectional view of B in FIG. 6.

FIG. 8 is an enlarged perspective view of C in FIG. 4.

FIG. 9 shows the loss characteristics of a wireless signal according to gaps between the bottom of a subject-to-be-tested and the top of a shielding wall.

FIG. 10 is a cross-sectional view of a socket block according to another embodiment of the disclosure.

### BEST MODEL

Below, a test device 100 according to an embodiment of the disclosure will be described with reference to the accompanying drawings.

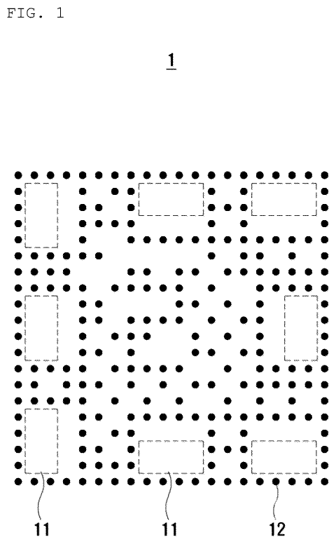

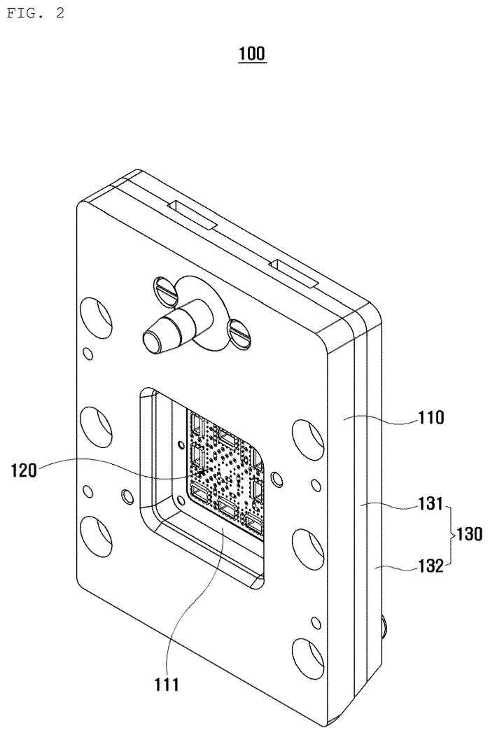

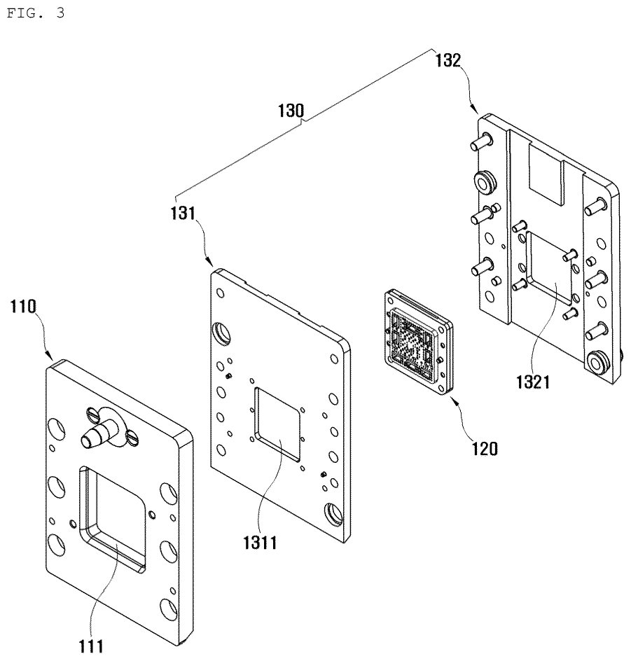

FIG. 1 is a view showing a subject-to-be-tested 1 viewed from below, FIG. 2 is a perspective view of the test device 100 according to an embodiment of the disclosure, and FIG. 3 is an exploded perspective view of the test device 100 in FIG. 2.

Referring to FIG. 1, the subject-to-be-tested 1 refers to a thing, the electrical characteristics and antenna characteristics of which will be subjected to a test. For example, the subject-to-be-tested 1 may be a semiconductor device including a plurality of built-in patch antennas 11. The subject-to-be-tested 1 includes a plurality of terminals 12 protruding in the form of bumps on the bottom thereof. The plurality of terminals 12 includes a signal terminal, a ground terminal, and a power terminal.

Referring to FIGS. 2 and 3, the test device 100 is to test the electrical characteristics and antenna characteristics of the subject-to-be-tested 1 of FIG. 1, and includes a test object insertion block 110, a socket block 120, and a block supporter 130.

The test object insertion block 110 includes a test object accommodating portion 111 that accommodates the subject-to-be-tested 1 to perform a test.

The socket block 120 has one side exposed to the test object accommodating portion 111 as shown in FIG. 2 while being supported in the block supporter 130.

The block supporter 130 includes a first block supporter 131 and a second block supporter 132. The socket block 120 is interposed between the first block supporter 131 and the second block supporter 132.

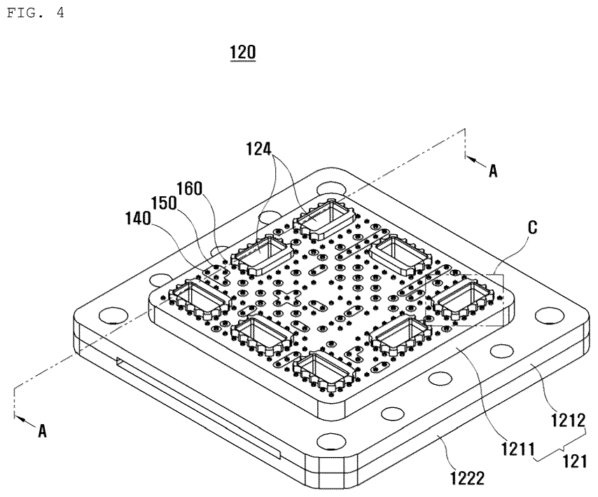

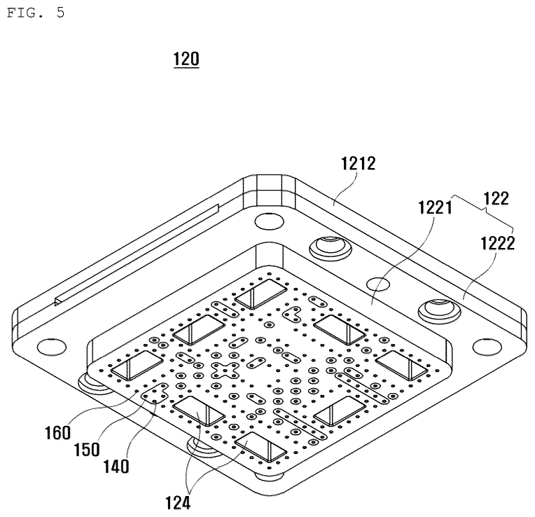

The first block supporter 131 includes a first opening 1311 that communicates with the test object accommodating portion 111 of the test object insertion block 110. The first opening 1311 accommodates an upper probe supporter 1211 (see FIG. 4), which protrudes from one side of the socket block 120, therein. The second block supporter 132 includes a second opening 1321. The second opening 1321 accommodates a lower probe supporter 1221 (see FIG. 5), which protrudes from an opposite side to the one side of the socket block 120, therein.

FIG. 4 is a perspective view of the socket block 120 in FIG. 2 viewed from above, and FIG. 5 is a perspective view of the socket block 120 of FIG. 2 vied from below.

Referring to FIGS. 4 and 5, the socket block 120 includes the upper and lower probe supporters 1211 and 1221 to support a plurality of probes, i.e., a signal probe 140, a ground probe 150, and a power probe 160. The socket block 120 includes a waveguide 124 corresponding to the antenna 11 of the subject-to-be-tested 1 and penetrating therethrough in the lengthwise direction of the signal probe 140 to measure the wireless signal in a different area from the upper and lower probe supporters 1211 and 1221.

The socket block 120 may be made of a conductive material, for example, brass. The socket block 120 includes an upper block 121 and a lower block 122.

The upper block 121 includes an upper probe supporter 1211 and an upper skirt portion 1212.

The upper probe supporter 1211 supports each upper portion of the signal probe 140, the ground probe 150 and the power probe 160 respectively corresponding to the signal terminal, the ground terminal and the power terminal of the subject-to-be-tested 1.

The upper skirt portion 1212 is coupled to a lower skirt portion 1222.

The lower block 122 includes a lower probe supporter 1221 and the lower skirt portion 1222.

The lower probe supporter 1221 supports each lower portion of the signal probe 140, the ground probe 150 and the power probe 160.

The lower skirt portion 1222 is coupled to the upper skirt portion 1212.

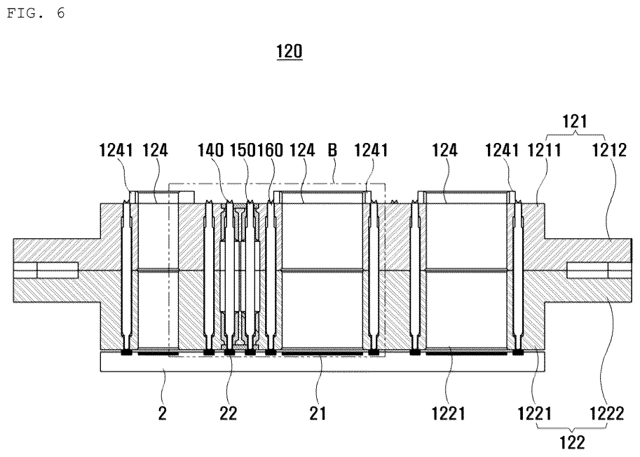

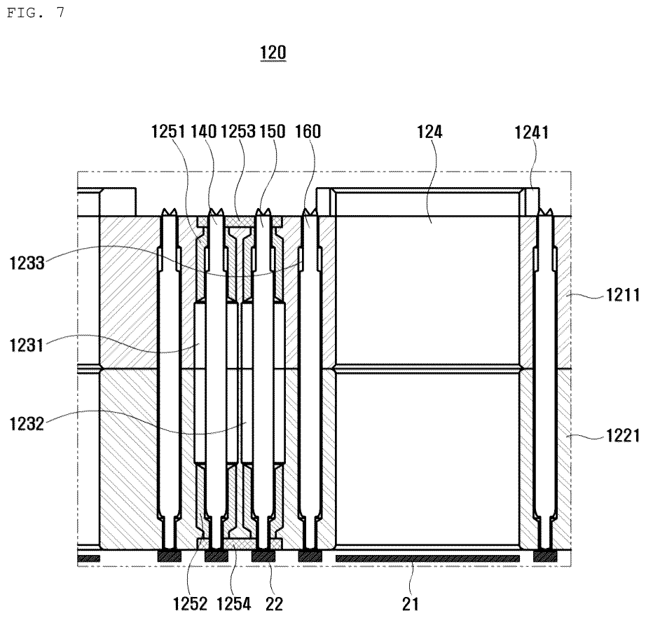

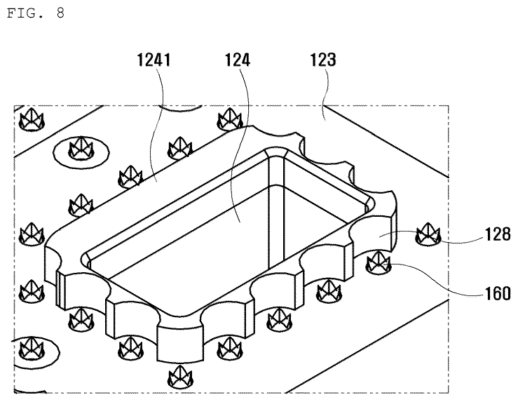

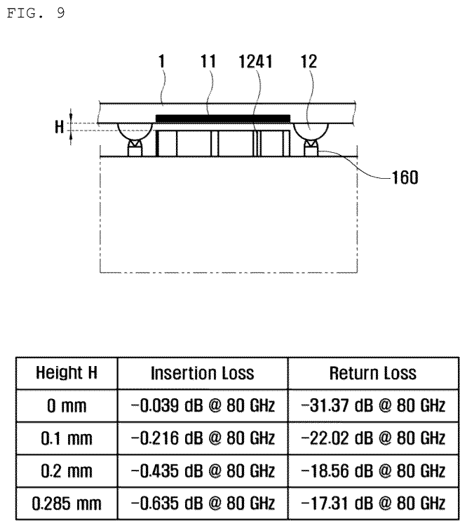

FIG. 6 is a cross-sectional view taken along line A-A in FIG. 4, FIG. 7 is an enlarged view of B in FIG. 6, FIG. 8 is an enlarged perspective view of C in FIG. 4, and FIG. 9 shows the loss characteristics of a wireless signal according to gaps between the bottom of the subject-to-be-tested 1 and the top of a shielding wall 1241.

Referring to FIGS. 6 and 7, the socket block 120 has a signal probe hole 1231, a power probe hole 1232 and a ground probe hole 1233 to respectively support the signal probe 140, the power probe 150 and the ground probe 160. The signal probe 140 and the power probe 150 are supported in the signal probe hole 1231 and the power probe hole 1232 by insulation supporting members 1251 and 1252 so as not to be electrically connected to the socket block, and the ground probe 160 is supported in the ground probe hole 1233 so as to be electrically connected to the socket block.

The socket block 120 includes a first insulation cover member 1253 surrounding first end portions of the signal probe 140 and the power probe 150 on one side thereof, and a second insulation cover member 1254 surrounding second end portions of the signal probe 140 and the power probe 150 on an opposite side to the one side. The first and second insulation cover members 1253 and 1254 can prevent the terminals 12 of the subject-to-be-tested 1 and the terminal 22 of a test circuit board 2 from a short-circuit as being in contact with the adjacent conductive probe supporters 1211 and 1221 during the test.

The waveguide 124 is formed to have a cross-sectional area corresponding to the size of the patch antenna 11 of the subject-to-be-tested 1 and penetrate the upper and lower probe supporters 1211 and 1221. The waveguide 124 refers to a passage through which a wireless signal emitted from the patch antenna 11 of the subject-to-be-tested 1 is guided to the antenna 21 of the test circuit board 2. In this case, the patch antenna 11 of the subject-to-be-tested 1 is a transmission antenna, and the antenna 21 of the test circuit board 2 is a reception antenna.

Referring to FIGS. 8 and 9, the waveguide 124 includes the shielding wall 1241 protruding from one side of the socket block 120 facing the subject-to-be-tested 1 toward the patch antenna 11 of the subject-to-be-tested 1. In FIG. 9, the subject-to-be-tested 1 includes the terminal 12 protruding from the bottom thereof. Therefore, the wireless signal emitted from the antenna 11 during the test may be leak to the outside through a gap corresponding to a protrusion height. The wireless signal may be interfere with noise from the noise through a gap corresponding to a protrusion height. The shielding wall 1241 serves to block the gap, thereby preventing the wireless signal from leaking to the outside or interfering with noise. In other words, the height of the shielding wall 1241 may be set to satisfy the loss characteristics for the wireless signal when the terminal 12 of the subject-to-be-tested 1 is in contact with the signal probe 140, the power probe 150 and the ground probe 160. As the loss characteristics for the wireless signal, an insertion loss of −1 to 0 dB, and a return loss of −10 dB or less are required to be satisfied.

The height of the shielding wall 1241 is required to be smaller than the height of the terminal 12 of the subject-to-be-tested 1.

The shielding wall 1241 includes terminal guide grooves 128 recessed along a test direction so that the terminals 12 adjacent to the antenna 11 can be guided to move down upon the test.

The subject-to-be-tested 1 may be damaged by the shielding wall 1241 when the bottom thereof is in direct contact with the top of the shielding wall 1241. The subject-to-be-tested 1 is required to space the bottom thereof apart by a predetermined gap H from the top of the shielding wall 1241 without contact during the test as shown in FIG. 9. The larger the gap H, the worse the loss characteristics of the wireless signal.

FIG. 9 shows the insertion losses and the return losses when the gaps Hare 0 mm, 0.1 mm, 0.2 mm, and 0.285 mm. The insertion loss of −1 to 0 dB and the return loss of −10 dB or less are satisfied when the gap H is 0.285 mm or less, but such loss characteristics are not satisfied when the gap H is larger than 0.285 mm.

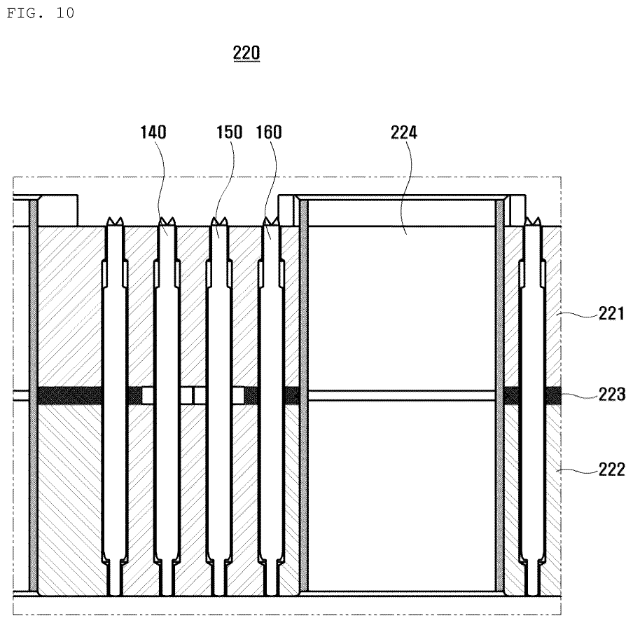

FIG. 10 is a cross-sectional view of a socket block 220 according to another embodiment of the disclosure.

The socket block 220 includes an upper block 221 made of an insulating material, a lower block 222 made of an insulating material, and a middle block 223 made of a conductive material. The socket block 220 supports the signal probe 140, the power probe 150, the ground probe 160, and a conductive waveguide 224.

The upper and lower blocks 221 and 222 support the signal probe 140, the power probe 150, and the ground probe 160 while being in contact therewith. The middle block 223 is not in contact with the signal probe 140 and the power probe 150, and is in contact with the ground probe 160 and the waveguide 224. Therefore, the middle block 223 serves as a conductive connector that connects the ground probe 160 and the waveguide 240 electrically.

The waveguide 224 is shaped to have a cross-section corresponding to the surface shapes that the antenna 11 of the subject-to-be-tested 1 and the antenna 24 of the test circuit board 2 have. The waveguide 224 may be implemented as a conductive tube or a conductive coating layer.

The test device according to an embodiment of the disclosure tests not only the electrical characteristics of the subject-to-be-tested but also the characteristics of the built-in patch antenna at a time, thereby reducing test time and test costs.

In the foregoing description, the disclosure and its advantages have been described with reference to specific embodiments. However, it will be apparent to a person having ordinary skill in the art that various modifications and changes can be made without departing from the scope of the disclosure as set forth in the appended claims. Accordingly, the disclosure and the drawings are to be regarded as examples rather than restrictions. All such possible modifications are to be made within the scope of the disclosure.

1. A test device for testing characteristics of a subject-to-be-tested with a built-in antenna that emits a wireless signal, the test device comprising:
a signal probe comprising one end portion to be in contact with a first terminal of the subject-to-be-tested to transmit a test signal;
a ground probe to be in contact with a second terminal of the subject-to-be-tested; and
a socket block comprising a probe supporter to support the signal probe and the ground probe, and a waveguide corresponding to the antenna of the subject-to-be-tested and penetrating therethrough in a lengthwise direction of the signal probe to measure the wireless signal in a different area from the probe supporter.

2. The test device of claim 1, wherein the waveguide comprises a shielding wall protruding from one side of the socket block facing the subject-to-be-tested toward the antenna.

3. The test device of claim 2, wherein the shielding wall has a height set to satisfy loss characteristics of the wireless signal when the first terminal and the second terminal of the subject-to-be-tested are in contact with the signal probe and the ground probe, respectively.

4. The test device of claim 2, wherein the shielding wall comprises terminal guide grooves recessed along a test direction to guide the second terminal to move down upon a test.

5. The test device of claim 1, wherein the probe supporter and the waveguide comprise a conductive material.

6. The test device of claim 1, wherein
the probe supporter comprises an insulating material,
the waveguide comprises a conductive material, and
the socket block comprises a conductive connector that connects the ground probe and the waveguide.
